(19) United States
(12) Patent Application Publication
(10) Pub. No.: US 2019/0281700 A1
(43) Pub. Date: Sep. 12, 2019

(54) FLEXIBLE FILM AND DISPLAY APPARATUS HAVING THE SAME

(71) Applicant: SAMSUNG DISPLAY CO., LTD., Yongin-si (KR)

(72) Inventors: Kihyun PYUN, Gwangmyeong-si (KR); Min-Soo CHOI, Hwaseong-si (KR); Yongsu LIM, Seoul (KR)

(21) Appl. No.: 16/261,947

(22) Filed: Jan. 30, 2019

(30) Foreign Application Priority Data
Mar. 8, 2018 (KR) 10-2018-0027582

(51) Int. Cl. H05K 1/14; H05K 1/11; H05K 1/18

(52) U.S. Cl. CPC H05K 1/147; H05K 1/118; H05K 1/189; G02F 1/13452; H05K 2201/09227; H05K 2201/10128; H05K 2201/09681; H05K 2201/093

(57) ABSTRACT

A flexible film includes: a flexible first layer; a common ground wiring on the first layer; an insulation layer on the first layer on which the common ground wiring is arranged; a first ground wiring on the insulation layer, and connected to the common ground wiring through a first contact hole formed through the insulation layer; a first signal line on the insulation layer and to which a first signal is applied; a second signal line on the insulation layer, adjacent to the first signal line, and to which a second signal, which is an inverted signal of the first signal, is applied; and a first sub-ground wiring on the insulation layer, and connected to the common ground wiring through a second contact hole formed through the insulation layer.

### CROSS-REFERENCE TO RELATED APPLICATION

This application claims priority to and the benefit of Korean Patent Application No. 10-2018-0027582, filed on Mar. 8, 2018 in the Korean Intellectual Property Office, the entire content of which is herein incorporated by reference.

### BACKGROUND

### 1. Field

Aspects of embodiments of the inventive concept relate to a flexible film and a display apparatus including the flexible film. Further, aspects of example embodiments of the inventive concept relate to a flexible film including a ground wiring and a display apparatus including the flexible film.

### 2. Description of the Related Art

Recently, a display apparatus having light weight and small size has been manufactured. A cathode ray tube (CRT) display apparatus has been used due to a performance and a competitive price. However the CRT display apparatus has a weakness with a size or portability. Therefore, a display apparatus such as a plasma display apparatus, a liquid crystal display apparatus, and an organic light emitting display apparatus has been highly regarded due to small size, light weight and low power consumption.

The display apparatus includes a display panel in which an image is displayed, and a driver for driving the display panel. A flexible film may be used to connect the driver to the display panel or to connect a plurality of drivers to each other. When the display apparatus has a high resolution, the number of wirings required for the flexible film also increases, and display quality deterioration due to mutual influence between adjacent wirings may (i.e. coupling capacitance) occur.

### SUMMARY

According to an aspect of one or more embodiments of the inventive concept, a flexible film has a reduced number of terminals, and degradation of a display quality may be prevented or substantially prevented.

According to another aspect of one or more embodiments of the inventive concept, a display apparatus includes the flexible film.

According to one or more embodiments of the inventive concept, a flexible film includes: a flexible first layer; a common ground wiring on the first layer; an insulation layer on the first layer on which the common ground wiring is arranged; a first ground wiring on the insulation layer, and connected to the common ground wiring through a first contact hole formed through the insulation layer; a first signal line on the insulation layer and to which a first signal is applied; a second signal line on the insulation layer, adjacent to the first signal line, and to which a second signal, which is an inverted signal of the first signal, is applied; and a first sub-ground wiring on the insulation layer, and connected to the common ground wiring through a second contact hole formed through the insulation layer.

In one or more embodiments, the flexible film may further include a second ground wiring on the insulation layer, spaced apart from the first ground wiring, and electrically connected to the common ground wiring through a third contact hole formed through the insulation layer. The first signal line, the second signal line, and the first sub-ground wiring may be between the first ground wiring and the second ground wiring.

In one or more embodiments, the flexible film may further include a third signal line on the insulation layer between the first ground wiring and the second ground wiring, and a fourth signal line on the insulation layer between the first ground wiring and the second ground wiring. The third signal line and the fourth signal line may be directly adjacent to each other. A signal applied to the third signal wiring may be an inverted signal of a signal applied to the fourth signal wiring. The first sub-ground wiring may be between the second signal line and the third signal line.

In one or more embodiments, the first layer may have a U-shape. The first ground wiring, the first signal line, the second signal line, and the first sub-ground wiring may extend along the U-shape.

In one or more embodiments, the flexible film may further include a first terminal at an end of the first signal line, a second terminal at an end of the second signal line, and a first ground terminal at an end of the first ground wiring. A width of the first terminal may be greater than a width of the first signal line. A width of the second terminal may be greater than a width of the second signal line. A width of the first ground terminal may be greater than a width of the first ground wiring.

In one or more embodiments, an interval between the first signal line and the second signal line may be smaller than an interval between the first terminal and the second terminal.

In one or more embodiments, the flexible film may further include a second layer on the first ground wiring, the first signal line, and the first sub-ground wiring. A terminal opening may be formed through the second layer to expose the first terminal, the second terminal, and the first ground terminal, and the first sub-ground wiring may not overlap the terminal opening.

In one or more embodiments, the common ground wiring may have a mesh structure.

According to one or more embodiments of the inventive concept, a display apparatus includes: a display panel, a first printed circuit board electrically connected to the display panel, a second printed circuit board adjacent to the first printed circuit board and electrically connected to the display panel, and a first U-film connecting the first printed circuit board and the second printed circuit board, and having a U-shape. The first U-film may include a flexible first layer, a common ground wiring on the first layer, an insulation layer on the first layer on which the common ground wiring is arranged, a first ground wiring on the insulation layer, and connected to the common ground wiring through a first contact hole formed through the insulation layer, a first signal line on the insulation layer and to which a first signal is applied, a second signal line on the insulation layer, adjacent to the first signal line, and to which a second signal, which is an inverted signal of the first signal, is applied, and a first sub-ground wiring on the insulation layer, and connected to the common ground wiring through a second contact hole formed through the insulation layer.

In one or more embodiments, the first U-film may further include a second ground wiring on the insulation layer, spaced apart from the first ground wiring, and electrically connected to the common ground wiring through a third contact hole formed through the insulation layer. The first signal line, the second signal line, and the first sub-ground wiring may be between the first ground wiring and the second ground wiring.

In one or more embodiments, the first U-film may further include a third signal line on the insulation layer between the first ground wiring and the second ground wiring, and a fourth signal line on the insulation layer between the first ground wiring and the second ground wiring. The third signal line and the fourth signal line may be directly adjacent to each other. A signal applied to the fourth signal wiring may be an inverted signal of a signal applied to the third signal wiring. The first sub-ground wiring may be between the second signal line and the third signal line.

In one or more embodiments, the first U-film may further include a first terminal, a second terminal, and a first ground terminal formed at an end of the first ground wiring. A width of the first terminal may be greater than a width of the first signal line. A width of the second terminal may be greater than a width of the second signal line. A width of the first ground terminal may be greater than a width of the first ground wiring.

In one or more embodiments, an interval between the first signal line and the second signal line of the first U-film may be smaller than an interval between the first terminal and the second terminal.

In one or more embodiments, the first U-film may further include a second layer on the first ground wiring, the first signal line, and the first sub-ground wiring. A terminal opening may be formed through the second layer to expose the first terminal, the second terminal, and the first ground terminal, and the first sub-ground wiring may not overlap the terminal opening.

In one or more embodiments, the first printed circuit board may include a first connector. The second printed circuit board may include a second connector. The first terminal, the second terminal, and the first ground terminal of the first U-film may be connected to the first connector or the second connector through the terminal opening.

In one or more embodiments, the first U-film may further include a handle on a surface of the first layer opposite to a surface on which the common ground wiring is arranged.

In one or more embodiments, the common ground wiring may have a mesh structure.

In one or more embodiments, the display apparatus may further include a host line electrically connected to the second printed circuit board, and a driving substrate electrically connected to the host line to generate a signal to drive the display panel.

In one or more embodiments, the first printed circuit board may include a first data driving chip, and the second printed circuit board may include a second data driving chip.

According to one or more embodiments of the inventive concept, a display apparatus includes a display panel, a printed circuit board electrically connected to the display panel, and comprising a connector, and a flexible film connected to the printed circuit board through the connector. The flexible film includes a first layer, a common ground wiring on the first layer and extending in a first direction, an insulation layer on the common ground wiring, a first sub-ground wiring on the insulation layer, connected to the common ground wiring through a first contact hole formed through the insulation layer, and extending in a second direction crossing the first direction, a second sub-ground wiring on the insulation layer, connected to the common ground wiring through a second contact hole formed through the insulation layer, and extending in the second direction, and first and second signal lines on the insulation layer, paired adjacent to each other, and between the first sub-ground wiring and the second sub-ground wiring.

According to an aspect of the display apparatus according to one or more embodiments of the present invention, the first or second ground wiring or the first, second or third sub-ground wiring may be arranged between the signal lines (for example, first and second signal lines) paired with each other and other signal lines adjacent to the signal lines paired with each other. Accordingly, the paired signal lines for transmitting signals inverted from each other can reduce signal distortion due to the influence of peripheral signal lines (e.g., a shield effect).

According to another aspect of the display apparatus according to one or more embodiments of the present invention, since the sub-ground wiring does not have a separate terminal, the sub-ground wiring is not directly connected to the connector of the printed circuit board (e.g., the first connector of the first printed circuit board), and the ground voltage may be applied to the sub-ground wiring through the common ground wiring and the first or second ground wiring. Accordingly, the number of terminals to which the ground voltage is applied can be reduced. In particular, when the number of required signal lines increases as the display apparatus becomes high-resolution, the number of the terminals can be reduced even though ground wirings (sub-ground wirings) between signal wirings are provided. For example, if it is necessary to form 114 terminals when terminals are formed for each of the sub-ground wirings, according to an embodiment of the present invention, the number of terminals required can be reduced to 96 or less. Accordingly, a conventional 96-pin connector can be used as the connector of the printed circuit board, and the manufacturing cost of the connector can be reduced.

In addition, since the overall width of the flexible film can be reduced, the structure of the driver of the display apparatus can be simplified.

It is to be understood that both the foregoing description and the following detailed description are exemplary and explanatory and are intended to provide further explanation of the invention as claimed.

### BRIEF DESCRIPTION OF THE DRAWINGS

The above and other features of the inventive concept will become more apparent by describing in further detail some example embodiments thereof with reference to the accompanying drawings, in which:

FIG. 1 is a block diagram illustrating a display apparatus according to an example embodiment of the inventive concept;

FIG. 2 is a plan view illustrating a portion of the display apparatus of FIG. 1;

FIG. 3 is a plan view illustrating a first U-film of the display apparatus of FIG. 2;

FIGS. 4A, 4B, and 4C are plan views for respectively explaining a wiring arrangement of a first layer, a wiring arrangement of a second layer, and a combined arrangement of these, respectively, of the first U-film of FIG. 3;

FIGS. 5A, 5B, and 5C are enlarged views for explaining the wiring arrangement of the first layer, the wiring arrangement of the second layer, and the combined arrangement of these, respectively, of the first U-film corresponding to a region “A” of FIG. 4C;

FIG. 6A is a cross-sectional view of the first U-film taken along the line I-I′ in FIG. 5C;

FIG. 6B is a cross-sectional view of the first U-film taken along the line II-II′ in FIG. 5C;

FIGS. 7A, 7B, and 7C are plan views for explaining a wiring arrangement of a first layer, a wiring arrangement of a second layer, and a combined arrangement of these, respectively, of a first U-film of a display apparatus according to an example embodiment of the inventive concept;

FIGS. 8A, 8B, and 8C are enlarged views for explaining the wiring arrangement of the first layer, the wiring arrangement of the second layer, and the combined arrangement of these, respectively, of the first U-film corresponding to a region ‘B’ of FIG. 7C;

FIG. 9A is a cross-sectional view of the first U-film taken along the line III-III′ in FIG. 8C; and

FIG. 9B is a cross-sectional view of the first U-film taken along the line IV-IV′ in FIG. 8C.

### DETAILED DESCRIPTION

Herein, aspects of the inventive concept will be explained in further detail with reference to the accompanying drawings.

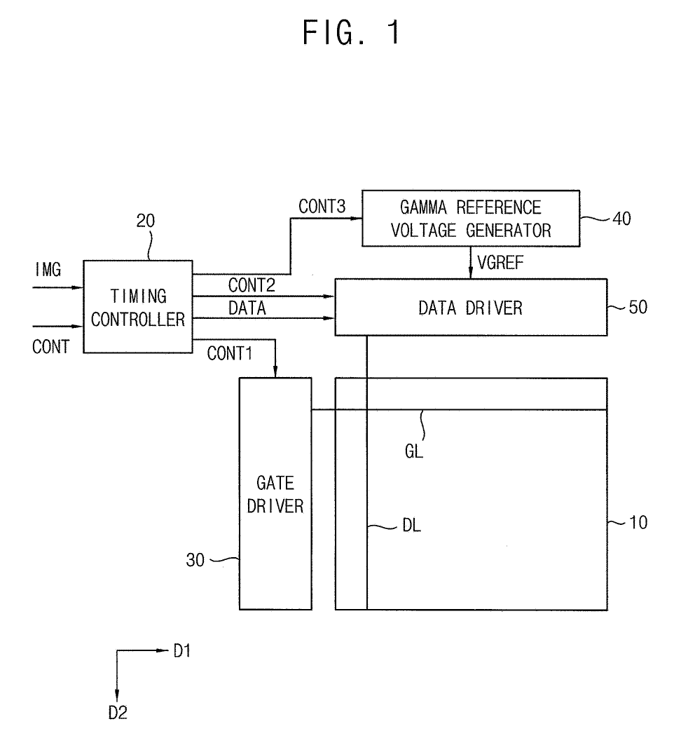

FIG. 1 is a block diagram illustrating a display apparatus according to an example embodiment of the inventive concept.

Referring to FIG. 1, according to an embodiment, a display apparatus may include a display panel 10 and a display panel driver. The display panel driver may include a timing controller 20, a gate driver 30, a gamma reference voltage generator 40, and a data driver 50. In an embodiment, the display apparatus may further include a backlight unit.

The display panel 10 may include a plurality of gate lines GL, a plurality of data lines DL and a plurality of pixels electrically connected to the gate lines GL and the data lines DL. The gate lines GL may extend in a first direction D1, and the data lines DL may extend in a second direction D2 crossing the first direction D1.

In an embodiment, the display panel 10 may include a first substrate, a second substrate facing the first substrate, and a liquid crystal layer disposed between the first substrate and the second substrate. The gate lines, the data lines, pixel electrodes of the pixels, and the switching elements may be formed on the first substrate. A common electrode may be formed on the second substrate.

The timing controller 20 may receive input image data IMG and an input control signal CONT from an external apparatus (not shown). In an embodiment, the input image data may include red image data, green image data, and blue image data. The input control signal CONT may include a master clock signal and a data enable signal. The input control signal CONT may further include a vertical synchronizing signal and a horizontal synchronizing signal.

The timing controller 20 may generate a first control signal CONT1, a second control signal CONT2, a third control signal CONT3, and a data signal DATA based on the input image data IMG and the input control signal CONT.

The timing controller 20 may generate the first control signal CONT1 for controlling an operation of the gate driver 30 based on the input control signal CONT, and output the first control signal CONT1 to the gate driver 30. The first control signal CONT1 may further include a vertical start signal and a gate clock signal.

The timing controller 20 may generate the second control signal CONT2 for controlling an operation of the data driver 50 based on the input control signal CONT, and output the second control signal CONT2 to the data driver 50. The second control signal CONT2 may include a horizontal start signal and a load signal.

The timing controller 20 may generate the data signal DATA based on the input image data IMG. The timing controller 20 may output the data signal DATA to the data driver 50.

The timing controller 20 may generate the third control signal CONT3 for controlling an operation of the gamma reference voltage generator 40 based on the input control signal CONT, and output the third control signal CONT3 to the gamma reference voltage generator 40.

The gate driver 30 may generate gate signals driving the gate lines GL in response to the first control signal CONT1 received from the timing controller 20. The gate driver 30 may sequentially output the gate signals to the gate lines GL.

The gamma reference voltage generator 40 may generate a gamma reference voltage VGREF in response to the third control signal CONT3 received from the timing controller 20. The gamma reference voltage generator 40 may provide the gamma reference voltage VGREF to the data driver 50. The gamma reference voltage VGREF may have a value corresponding to a level of the data signal DATA.

In an exemplary embodiment, the gamma reference voltage generator 40 may be disposed in the timing controller 20, or in the data driver 50.

The data driver 50 may receive the second control signal CONT2 and the data signal DATA from the timing controller 20, and receive the gamma reference voltage VGREF from the gamma reference voltage generator 40. The data driver 50 may convert the data signal DATA into data voltages having an analog type using the gamma reference voltage VGREF. The data driver 50 may output the data voltages to the data lines DL.

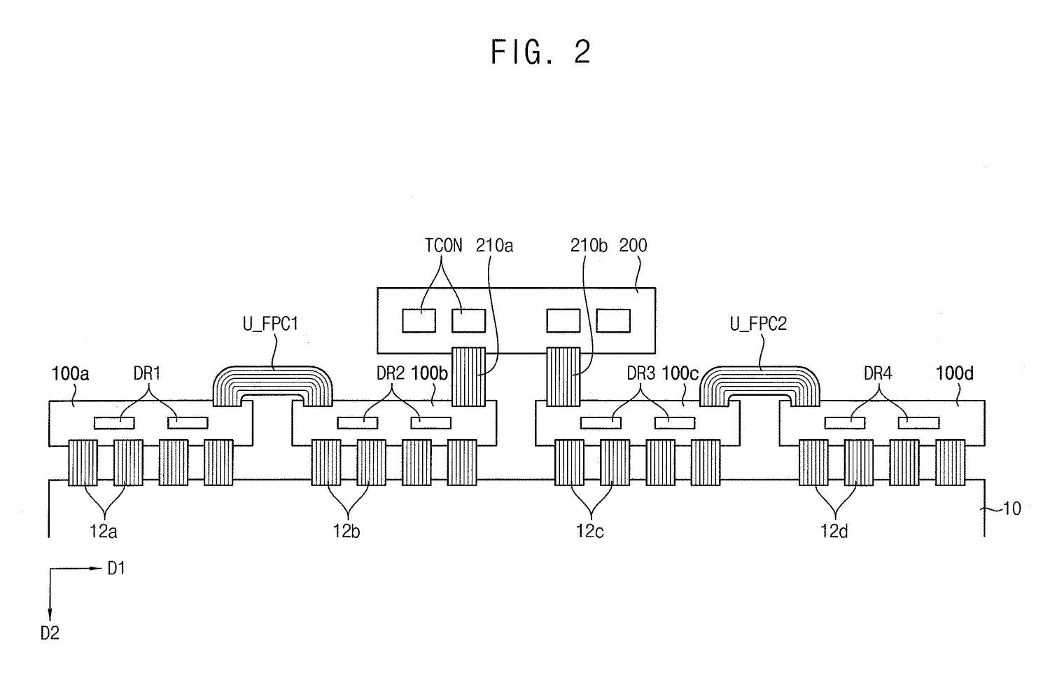

FIG. 2 is a plan view illustrating a portion of the display apparatus of FIG. 1.

Referring to FIG. 2, the display apparatus includes the display panel 10, a first connecting part 12a, a second connecting part 12b, a third connecting part 12c, a fourth connecting part 12d, a first printed circuit board 100a, a second printed circuit board 100b, a third printed circuit board 100c, a fourth printed circuit board 100d, a first data driving chip DR1, a second data driving chip DR2, a third data driving chip DR3, a fourth data driving chip DR4, a first U-film U_FPC1, a second U-film U_FPC2, a first host line 210a, a second host line 210b, a driving substrate 200, and a timing controller TCON.

The display panel 10 may include any of an organic light emitting display panel, a liquid crystal display panel, an electrowetting display panel, an electrophoretic display panel, a microelectromechanical system (MEMS) display panel, a plasma display panel, and the like.

For example, when the display panel 10 includes the liquid crystal display apparatus, the display panel 10 may include a first base substrate on which gate lines, data lines, pixels, and switching elements are formed, a second base substrate opposed to the first base substrate on which a common electrode is formed, and a liquid crystal layer disposed between the first base substrate and the second base substrate, as described above with reference to FIG. 1.

For example, when the display panel 10 includes the organic light emitting display panel, the display panel 10 may include a plurality of organic light emitting structures which emit light. For example, each of the organic light emitting structures may include a first electrode, a second electrode facing the first electrode, and an organic light emitting element disposed between the first electrode and the second electrode. The organic light emitting element may include a hole injection layer, a hole transfer layer, an emission layer, an electron transfer layer, and an electron injection layer.

The first connecting part 12a, the second connecting part 12b, the third connecting part 12c, and the fourth connecting part 12d may electrically connect the display panel 10 to the first printed circuit board 100a, the second printed circuit board 100b, the third printed circuit board 100c, and the fourth printed circuit board 100d, respectively.

The first printed circuit board 100a, the second printed circuit board 100b, the third printed circuit board 100c, and the fourth printed circuit board 100d may include the first data driving chip DR1, the second data driving chip DR2, the third data driving chip DR3, and the fourth data driving chip DR4, respectively, which provide electrical signals to the data lines. Each of the first printed circuit board 100a, the second printed circuit board 100b, the third printed circuit board 100c, and the fourth printed circuit board 100d may be disposed adjacent to the display panel 10. For example, the first printed circuit board 100a, the second printed circuit board 100b, the third printed circuit board 100c, and the fourth printed circuit board 100d may be disposed to be spaced apart from the display panel 10 in a second direction D2 which is perpendicular to a first direction D1 at one side of the display panel 10, and may be arranged in the first direction D1.

Some of the first to fourth printed circuit boards 100a, 100b, 100c, and 100d may be connected to the host line 210a, 210b which receives electrical signals from the driving substrate 200. The host line 210a, 210b may provide a power signal, an image signal, or the like. For example, the host line 210a, 210b may provide a gamma reference voltage (refer to VGREF in FIG. 1). For example, the host line 210a, 210b may provide any of the first to third control signals (refer to CONT1, CONT2, and CONT3 in FIG. 1), and a data signal (refer to DATA in FIG. 1).

The host line may include the first host line 210a and the second host line 210b. The first host line 210a may electrically connect the driving substrate 200 to the second printed circuit board 100b. The second host line 210b may electrically connect the driving substrate 200 to the third printed circuit board 100c.

The first printed circuit board 100a and the fourth printed circuit board 100d, which are not connected to the first host line 210a or the second host line 210b, may receive the electrical signals from the second printed circuit board 100b and the third printed circuit board 100c. For example, the first printed circuit board 100a disposed adjacent to the second printed circuit board 100b in an opposite direction of the first direction D1 may receive the electrical signals from the second printed circuit board 100b via the first U-film U_FPC1. In the same way, even when a plurality of printed circuit boards is included, the electrical signals may be received through the U-film connected to each other. Accordingly, the electrical signals provided from the first host line 210a may all be provided to the printed circuit boards arranged along the opposite direction of the first direction D1 from the second printed circuit board 100b.

Similarly, the fourth printed circuit board 100d disposed adjacent to the third printed circuit board 100c along the first direction D1 may receive the electrical signals from the third printed circuit board 100c via the second U-film U_FPC2. In the same way, even when a plurality of printed circuit boards is included, the electrical signals may be received through the U-film connected to each other. Accordingly, the electrical signals provided from the second host line 210b may all be provided to the printed circuit boards arranged along the first direction D1 from the third printed circuit board 100c.

The driving substrate 200 may include the timing controller TCON. The timing controller TCON may generate the first to third control signals and the data signal based on the input image data and the input control signal, as described above with reference to FIG. 1. In an embodiment, the driving substrate 200 may further include driving chips for generating necessary voltages and signals, for example, the gamma reference voltage.

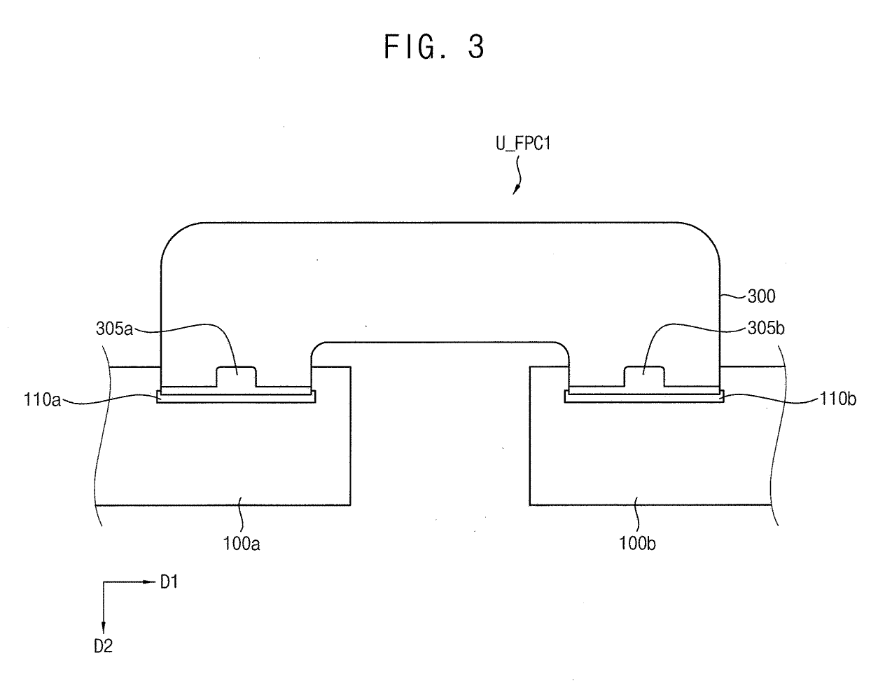

FIG. 3 is a plan view illustrating a first U-film of the display apparatus of FIG. 2.

Referring to FIG. 3, the first U-film U_FPC1 may include a film part 300, a first handle 305a, and a second handle 305b. The second U-film U_FPC2 of FIG. 2 may be substantially the same as the first U-film U_FPC1 and, therefore, only the first U-film U_FPC1 will be described in further detail.

The first U-film U_FPC1 can electrically connect the first printed circuit board 100a to the second printed circuit board 100b. The first U-film U_FPC1 may be connected to a first connector 110a of the first printed circuit board 100a and a second connector 110b of the second printed circuit board 100b.

The film part 300 may have a bending shape to connect to the first connecting portion 110a and the second connecting portion 110b. For example, the film part 300 may have a U-shape. For example, the film part 300 may extend in a direction opposite the second direction D2, and bend to extend in the first direction D1 and further bend to extend in the second direction D2. The film part 300 may include a plurality of signal lines L, terminals P formed at ends of the signal lines, and a sub-ground wiring GND surrounding two signal lines paired with each other.

The first handle 305a and the second handle 305b may be a grabbing portion for a factory worker when the first U-film U_FPC1 is connected to the first printed circuit board 100a and the second printed circuit board 100b for manufacturing the display apparatus.

In an embodiment, the first handle 305a and the second handle 305b may be made of a rigid material that is more rigid than the film unit 300. For example, the first handle 305a and the second handle 305b may include polyethylene terephthalate.

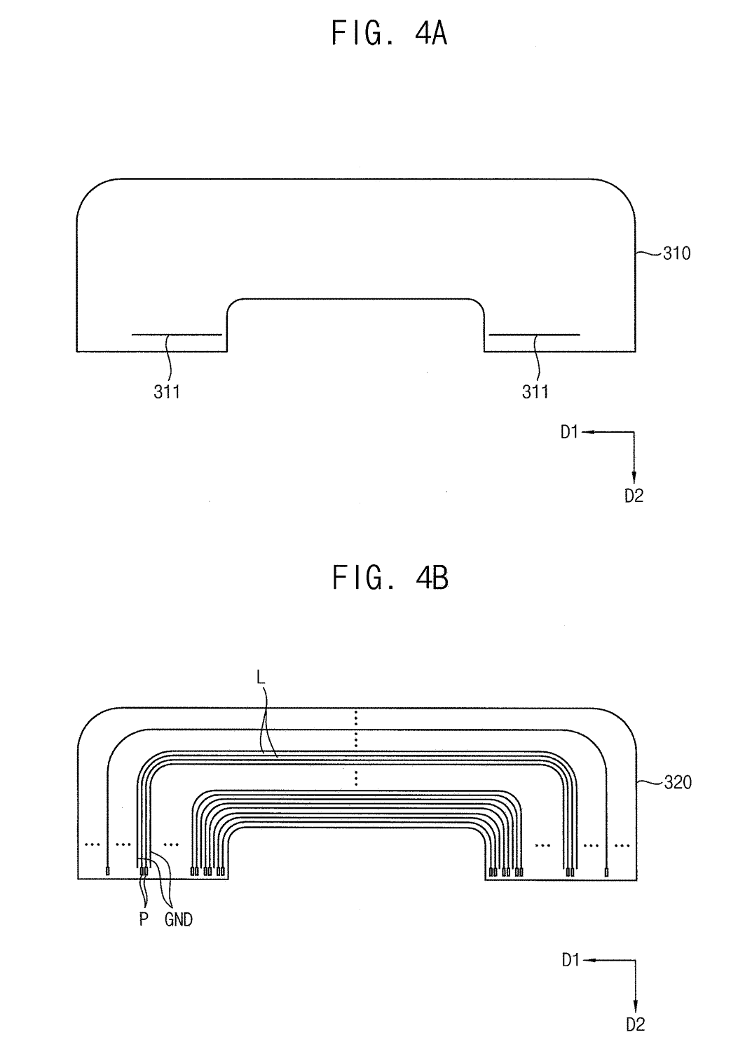

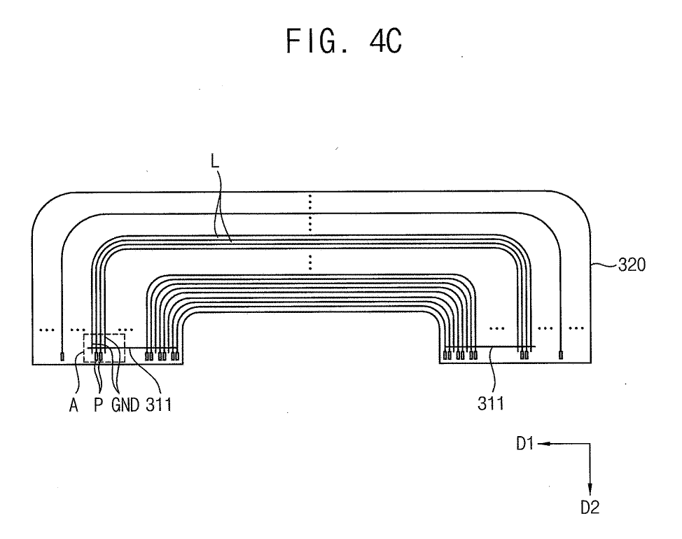

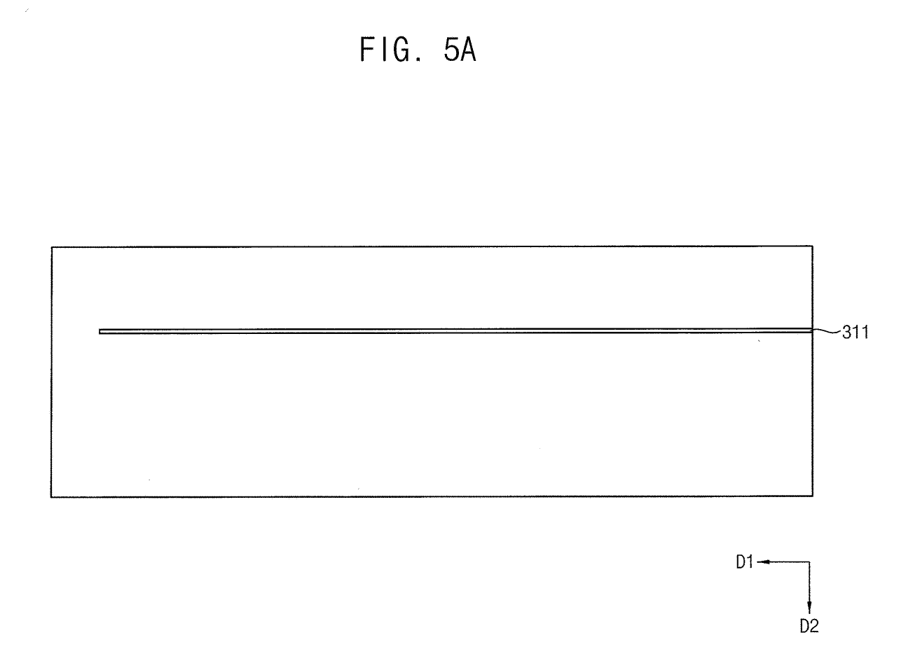

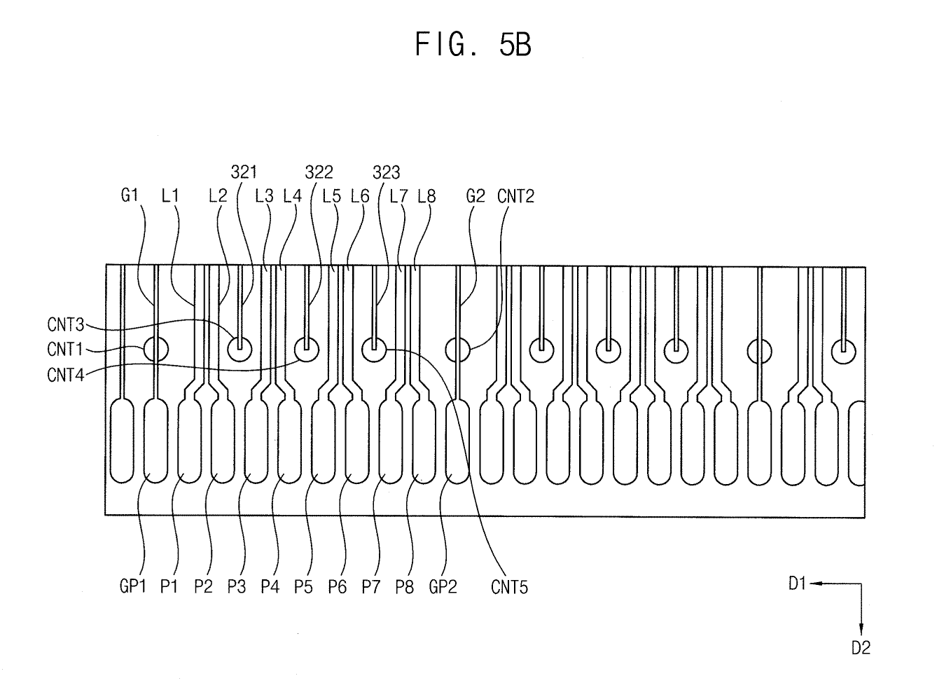

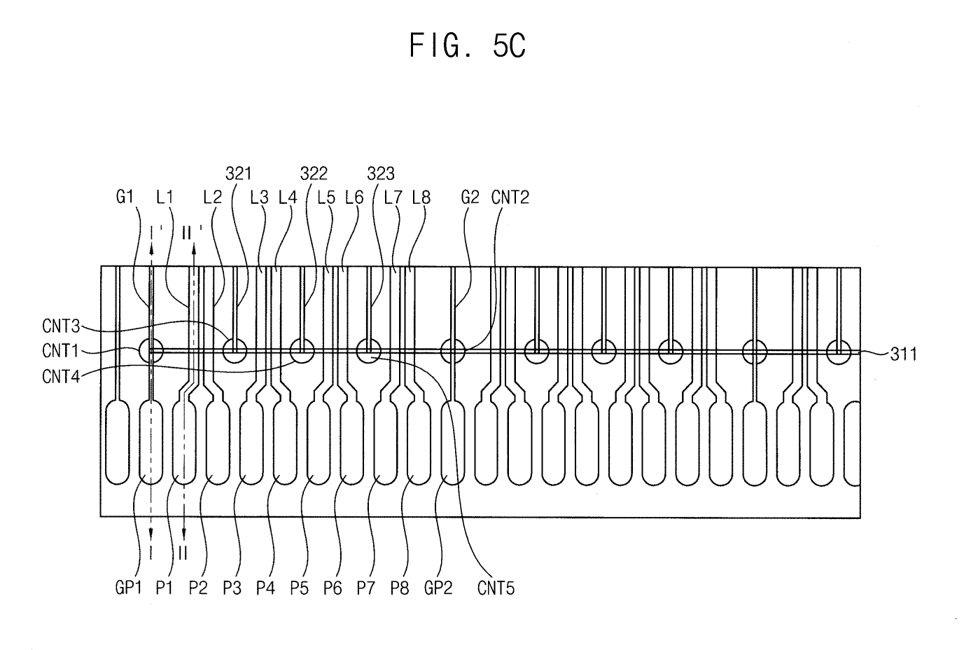

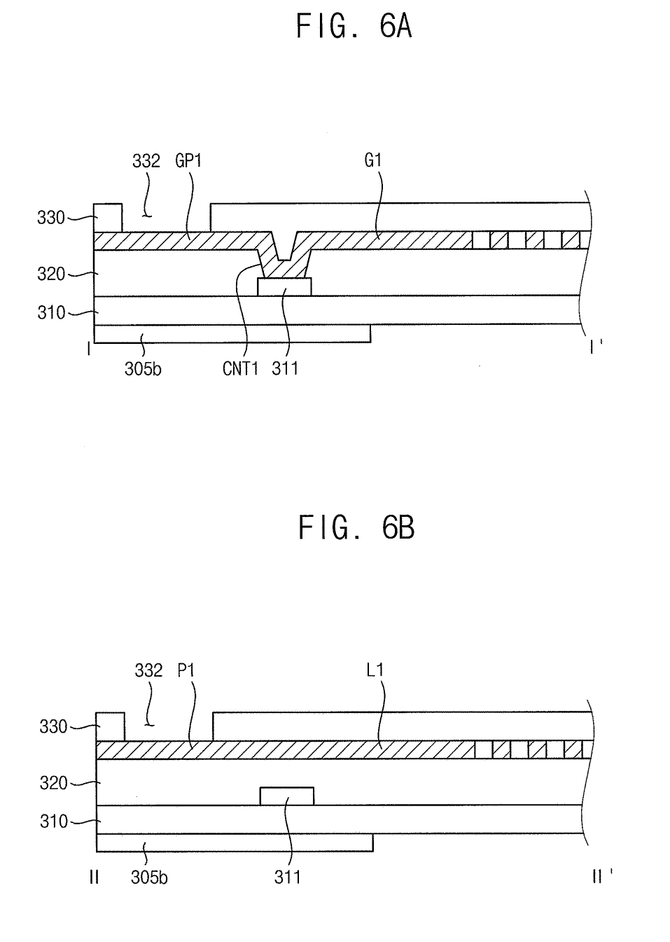

FIGS. 4A, 4B, and 4C are plan views for explaining a wiring arrangement of a first layer, a wiring arrangement of a second layer, and a combined arrangement of these, respectively, of the first U-film of FIG. 3. FIGS. 5A, 5B, and 5C are enlarged views for explaining the wiring arrangement of the first layer, the wiring arrangement of the second layer, and the combined arrangement of these, respectively, of the first U-film corresponding to a region “A” of FIG. 4C. FIG. 6A is a cross-sectional view of the first U-film taken along the line I-I′ in FIG. 5C. FIG. 6B is a cross-sectional view of the first U-film taken along the line II-II′ in FIG. 5C. Here, FIGS. 4A to 6B are views showing a back direction of the first U-film shown in FIG. 3.

Referring to FIGS. 4A to 6B, the first U-film U_FPC1 may include a first layer 310, a common ground wiring 311, an insulation layer 320, a first ground wiring G1, a second ground wiring G2, a first ground terminal GP1, a second ground terminal GP2, a plurality of signal lines L, a plurality of terminals P, a second layer 330, a terminal opening 332, and a sub-ground wiring. The signal lines L may include a first signal line L1, a second signal line L2, a third signal line L3, a fourth signal line L4, a fifth signal line L5, a sixth signal line L6, a seventh signal line L7, and an eighth signal line L8. The terminals P may include a first terminal P1, a second terminal P2, a third terminal P3, a fourth terminal P4, a fifth terminal P5, a sixth terminal P6, a seventh terminal P7, and an eighth terminal P8. The sub-ground wiring may include a first sub-ground wiring 321, a second sub-ground wiring 322, and a third sub-ground wiring 323.

The first layer 310 may be a flexible film. That is, the first layer 310 may include an insulating material having flexibility. In an embodiment, the first layer 310 may have a transparency (e.g., a predetermined transparency).

The common ground wiring 311 may be disposed on the first layer 310. The common ground wiring 311 may extend in a direction perpendicular to an extending direction of the plurality of signal lines L. In the present example embodiment, since the common ground wiring 311 is formed adjacent to the end of the U-shaped film (see the description of FIG. 3), it may extend in the first direction D1.

The insulation layer 320 may be disposed on the first layer 310 on which the common ground wiring 311 is disposed. The insulation layer 320 may include any of an organic or insulating material. For example, the insulation layer 320 may be a flexible film including an insulating material having flexibility.

The first ground wiring G1 and the second ground wiring G2 may be disposed on the insulation layer 320. In an embodiment, the first ground wiring G1 and the second ground wiring G2 may extend in a U shape along the film part 300.

The first ground terminal GP1 may be formed at an end of the first ground wiring G1. That is, the first ground terminal GP1 may be exposed by the terminal opening 332 of the second layer 330 and connected to the second handle or connector 305b of the second printed circuit board (refer to 100b of FIG. 3). A width of the first ground terminal GP1 may be greater than a width of the first ground wiring G1. As shown in the drawings, a terminal for connecting to the first connector (refer to 305a in FIG. 3) of the first printed circuit board (refer to 100a in FIG. 3) may be formed at the other end of the first ground wiring G1. Herein, all of the terminals may be formed at both ends of the wiring, and only one end will be described for convenience of explanation.

The second ground terminal GP2 may be formed at an end of the second ground wiring G2. That is, the second ground terminal GP2 may be exposed by the terminal opening 332 of the second layer 330 and connected to the second handle or connector 305b of the second printed circuit board (refer to 100b of FIG. 3). A width of the second ground terminal GP2 may be greater than a width of the second ground wiring G2.

The first ground wiring G1 may be electrically connected to the common ground wiring 311 through a first contact hole CNT1 formed through the insulation layer 320. The second ground line G2 may be electrically connected to the common ground wiring 311 through a second contact hole CNT2 formed through the insulation layer 320.

A ground voltage may be applied to the common ground wiring 311 and the first and second ground wirings G1 and G2 through the first and second ground terminals GP1 and GP2.

The first signal line L1, the second signal line L2, the third signal line L3, the fourth signal line L4, the fifth signal line L5, the sixth signal line L6, the seventh signal line L7, and the eighth signal line L8 may be disposed on the insulation layer 320 between the first ground wiring G1 and the second ground wiring G2. In an embodiment, each of the first to eighth signal lines L1 to L8 may extend in a U-shape along the film portion 300.

The first terminal P1, the second terminal P2, the third terminal P3, the fourth terminal P4, the fifth terminal P5, the sixth terminal P6, the seventh terminal P7, and the eighth terminal P8 may be formed at ends of the first signal line L1, the second signal line L2, the third signal line L3, the fourth signal line L4, the fifth signal line L5, the sixth signal line L6, the seventh signal line L7, and the eighth signal line L8, respectively. A width of each of the first to eighth terminals P1 to P8 may be greater than a width of each of the first to eighth signal lines L1 to L8.

The first signal line L1 and the second signal line L2 may be paired with each other. For example, a first signal is applied to the first signal line L1 and an inverted signal of the first signal, that is, a second signal, which is a differential signal, may be applied to the second signal line L2. Similarly, the third signal line L3 and the fourth signal line L4, the fifth signal line L5 and the sixth signal line L6, and the seventh signal line L7 and the eighth signal line L8 may also be paired. For example, signals applied to the third signal line L3 and the fourth signal line L4 may be inverted from each other, signals applied to the fifth signal line L5 and the sixth signal line L6 may be inverted from each other, and signals applied to the seventh signal line L7 and the eighth signal line L8 may be inverted from each other.

In an embodiment, an interval between the first signal line L1 and the second signal line L2 paired with each other may be narrower than an interval between the first terminal P1 and the second terminal P2. Similarly, an interval between the third signal line L3 and the fourth signal line L4 may be narrower than an interval between the third terminal P3 and the fourth terminal P4, an interval between the fifth signal line L5 and the sixth signal line L6 may be narrower than an interval between the fifth terminal P5 and the sixth terminal P6, and an interval between the seventh signal line L7 and the eighth signal line L8 may be narrower than an interval between the seventh terminal P7 and the eighth terminal P8. Accordingly, an interval between the second signal line L2 and the third signal line L3, an interval between the fourth signal line L4 and the fifth signal line L5, and an interval between the sixth signal line L6 and the seventh signal line L7 may be wider than the interval between the two signal lines paired with each other.

The first sub-ground wiring 321 may be disposed on the insulation layer 320 between the second signal line L2 and the third signal line L3. The second sub-ground wiring 322 may be disposed on the insulation layer 320 between the fourth signal line L4 and the fifth signal line L5. The third sub-ground wiring 323 may be disposed on the insulation layer 320 between the sixth signal line L6 and the seventh signal line L7.

The first sub-ground wiring 321 may be electrically connected to the common ground wiring 311 through a third contact hole CNT3 formed through the insulation layer 320. The second sub-ground wiring 322 may be electrically connected to the common ground wiring 311 through a fourth contact hole CNT4 formed through the insulation layer 320. The third sub ground line 323 may be electrically connected to the common ground wiring 311 through a fifth contact hole CNT5 formed through the insulation layer 320.

The ground voltage is applied to the first to third sub-ground wirings 321, 322, and 323. Thus, display quality degradation due to influence between the third signal line L3 and the fourth signal line L4, between the third terminal P3 and the fourth terminal P4, and between the fifth signal line L5 and the sixth signal line L6 can be prevented or substantially prevented. That is, the first to third sub-ground wirings 321, 322, and 323 or the ground wirings G1 and G2 to which the ground voltage is applied are disposed between the signal lines to prevent or substantially prevent signal distortion due to coupling capacitances and the like, such that deterioration of display quality can be prevented or substantially prevented.

The second layer 330 may be formed on the insulation layer 320 on which the first and second ground wirings G1 and G2, the first to eighth signal lines L1 to L8 and the first to third sub-ground wirings 321, 322, 323 are disposed. The terminal opening 332 may be formed through the second layer 330 to expose the first and second ground terminals GP1 and GP2, and the first to eighth terminals P1 to P8. The terminals exposed through the terminal opening 332 may contact the first or second connector of the first or second printed circuit board. In an embodiment, the second layer 330 may be a flexible film. That is, the second layer 330 may include an insulating material having flexibility. In an embodiment, the second layer 330 may have a transparency (e.g., a predetermined transparency).

The first and second handles 305a and 305b may be disposed on an outer surface of the first layer opposite to a surface on which the wirings are formed.

According to an aspect of the display apparatus according to an example embodiment of the present invention, the first or second ground wiring G1 or G2 or the first, second, or third sub-ground wiring 321, 322, 323 may be disposed between the signal lines (for example, the first and second signal lines L1 and L2) paired with each other and other signal lines adjacent to the signal lines paired with each other. Accordingly, the paired signal lines for transmitting signals inverted from each other can reduce signal distortion due to the influence of peripheral signal lines (e.g., a shield effect).

According to another aspect, since the sub-ground wiring does not have a separate terminal, the sub-ground wiring is not directly connected to the connector of the printed circuit board (for example, the first connector 110a of the first printed circuit board 100a), and the ground voltage may be applied to the sub-ground wiring through the common ground wiring 311 and the first or second ground wiring G1 or G2. Accordingly, the number of terminals to which the ground voltage is applied can be reduced. In particular, when the number of required signal lines increases as the display apparatus becomes high-resolution, the number of the terminals can be reduced even though ground wirings (sub-ground wirings) between signal wirings are provided. For example, if it is necessary to form 114 terminals when terminals are formed for each of the sub-ground wirings, according to an embodiment of the present invention, the number of terminals required can be reduced to 96 or less. Accordingly, a conventional 96-pin connector can be used as the connector of the printed circuit board, and the manufacturing cost of the connector can be reduced.

In addition, since the overall width of the flexible film can be reduced, a structure of the driver of the display apparatus can be simplified.

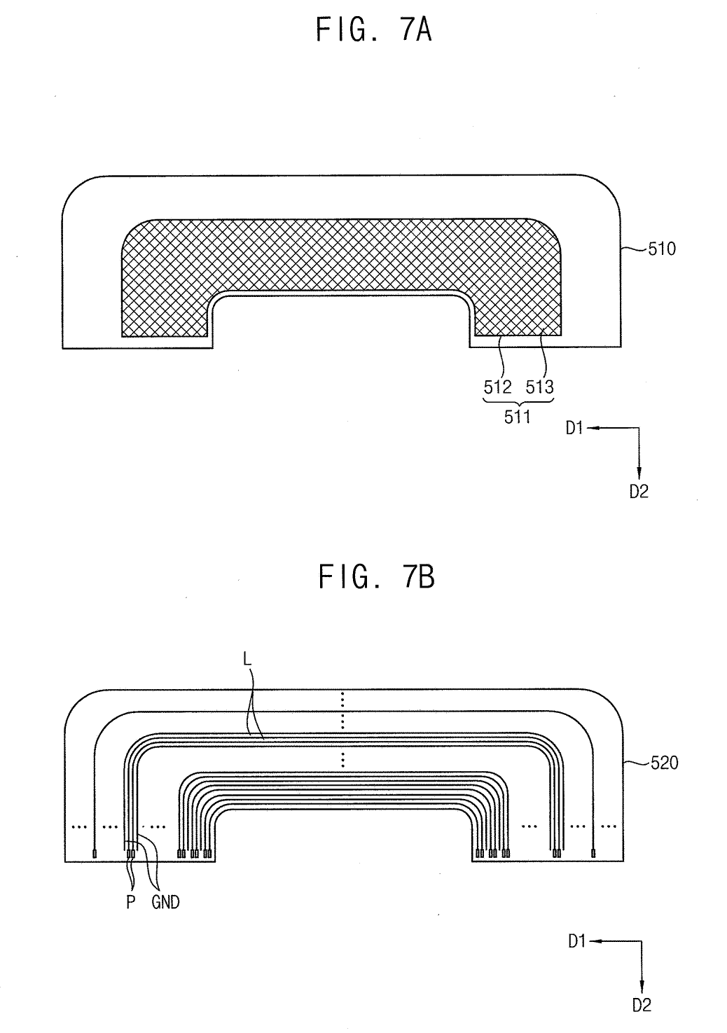

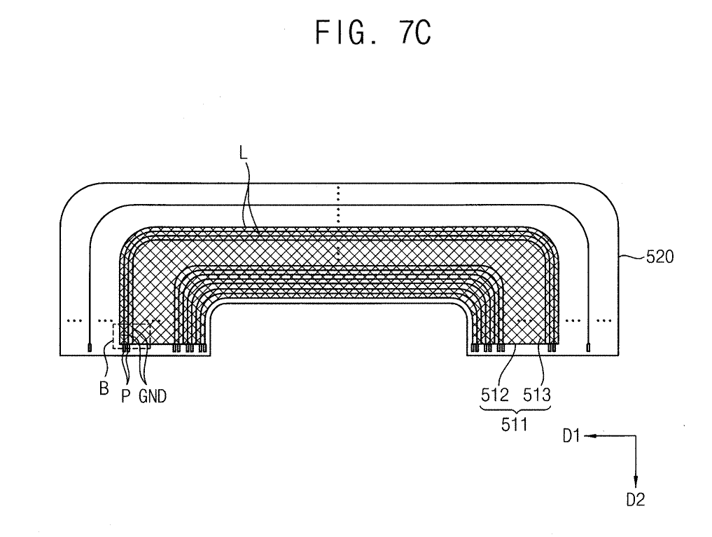

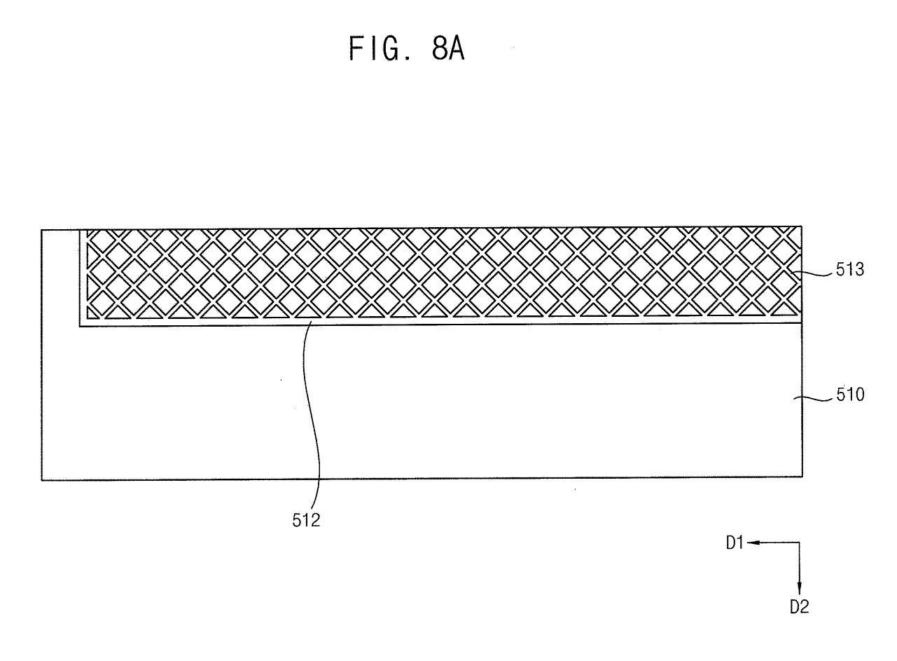

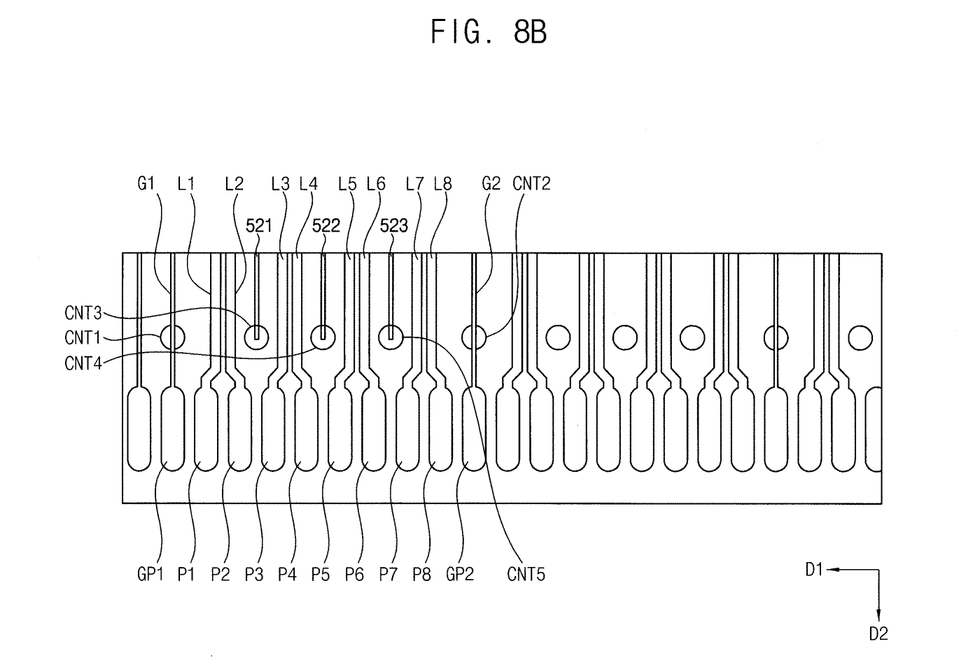

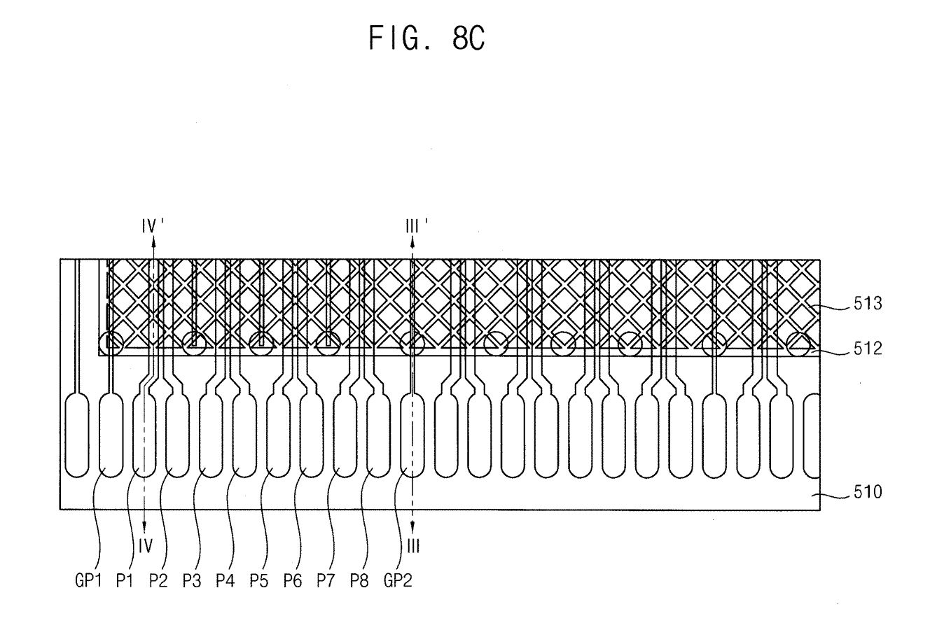

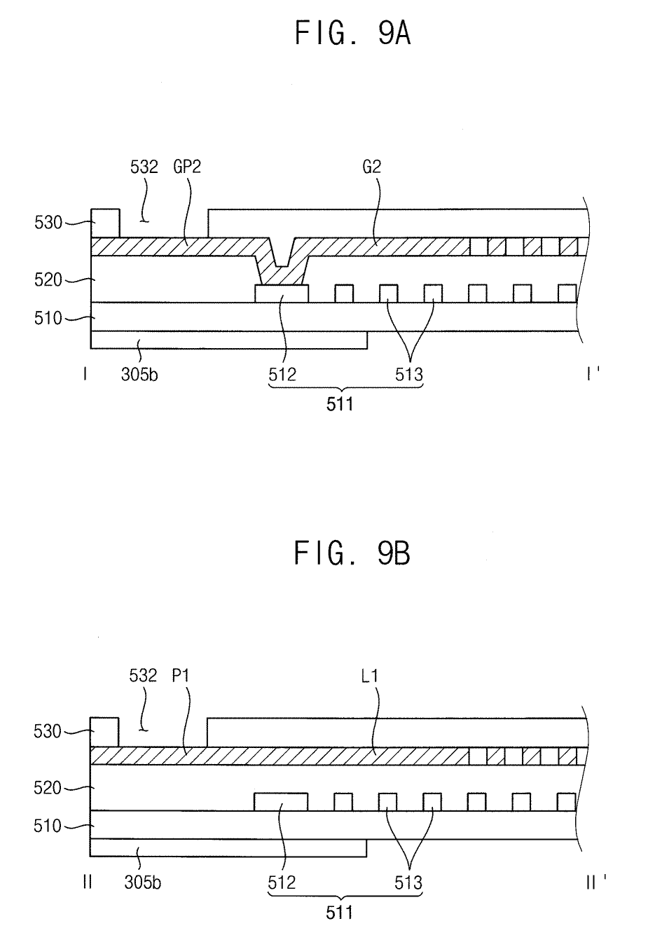

FIGS. 7A, 7B, and 7C are plan views for explaining a wiring arrangement of a first layer, a wiring arrangement of a second layer, and a combined arrangement of these, respectively, of a first U-film of a display apparatus according to an example embodiment of the inventive concept. FIGS. 8A, 8B, and 8C are enlarged views for explaining the wiring arrangement of the first layer, the wiring arrangement of the second layer, and the combined arrangement of these, respectively, of the first U-film corresponding to a region “B” of FIG. 7C. FIG. 9A is a cross-sectional view of the first U-film taken along the line III-III′ in FIG. 8C. FIG. 9B is a cross-sectional view of the first U-film taken along the line IV-IV′ in FIG. 8C.

Referring to FIGS. 7A to 9B, the display apparatus according to an embodiment may include a first U-film substantially the same as the first U-film of FIGS. 4A to 6B, except for a common ground wiring 511 of a first U-film.

The first U-film may include a first layer 510, a common ground wiring 511, an insulation layer 520, a first ground wiring G1, a second ground wiring G2, a first ground terminal GP1, a second ground terminal GP2, a plurality of signal lines L, a plurality of terminals P, a second layer 530, a terminal opening 532, a first sub-ground wiring 521, a second sub-ground wiring 522, and a third sub-ground wiring 523. The signal lines L may include a first signal line L1, a second signal line L2, a third signal line L3, a fourth signal line L4, a fifth signal line L5, a sixth signal line L6, a seventh signal line L7, and an eighth signal line L8. The terminals P may include a first terminal P1, a second terminal P2, a third terminal P3, a fourth terminal P4, a fifth terminal P5, a sixth terminal P6, a seventh terminal P7, and an eighth terminal P8.

The common ground wiring 511 may be disposed on the first layer 310. The common ground wiring 511 may include a horizontal portion 512 and a mesh portion 513.

The horizontal portion 512 may extend along the first direction D1 and may cross a plurality of signal lines. The mesh portion 513 may extend from the horizontal portion 512 in a second direction D2 crossing the first direction D1 to form a mesh structure. Shielding effect by the ground voltage can be improved by forming the common ground wiring 511 in a mesh structure. Thus, the first ground wiring G1, the second ground wiring G2, the first sub-ground wiring 521, the second sub-ground wiring 522, and the third sub-ground wiring 523 are electrically connected to the common ground wiring 511 through a first contact hole CNT1, a second contact hole CNT2, a third contact hole CNT3, a fourth contact hole CNT4, and a fifth contact hole CNT5 formed through the insulation layer 520.

The mesh portion 513 of the common ground wiring 511 overlaps the first to eighth wiring lines L1 to L8, such that it is possible to shield external influences that may distort the signals applied to the first to eighth lines L1 to L8.

The insulation layer 520 may be disposed on the first layer 510 on which the common ground wiring 511 is disposed. The first ground wiring G1 and the second ground wiring G2 may be disposed on the insulation layer 520.

The first signal line L1, the second signal line L2, the third signal line L3, the fourth signal line L4, the fifth signal line L5, the sixth signal wiring L6, the seventh signal line L7, and the eighth signal wiring L8 are disposed on the insulation layer 520 between the first ground wiring G1 and the second ground wiring G2.

According to an aspect of the display apparatus according to example embodiments of the present invention, the first or second ground wiring or the first, second, or third sub-ground wiring may be disposed between the signal lines (for example, first and second signal lines) paired with each other and other signal lines adjacent to the signal lines paired with each other. Accordingly, the paired signal lines for transmitting signals inverted from each other can reduce signal distortion due to the influence of peripheral signal lines (e.g., a shield effect).

According to another aspect, since the sub-ground wiring does not have a separate terminal, the sub-ground wiring is not directly connected to the connector of the printed circuit board (for example, the first connector of the first printed circuit board), and the ground voltage may be applied to the sub-ground wiring through the common ground wiring and the first or second ground wiring. Accordingly, the number of terminals to which the ground voltage is applied can be reduced. In particular, when the number of required signal lines increases as the display apparatus becomes high-resolution, the number of the terminals can be reduced even though ground wirings (sub-ground wirings) between signal wirings are provided. For example, if it is necessary to form 114 terminals when terminals are formed for each of the sub-ground wirings, according to an embodiment of the present invention, the number of terminals required can be reduced to 96 or less. Accordingly, a conventional 96-pin connector can be used as the connector of the printed circuit board, and the manufacturing cost of the connector can be reduced.

In addition, since the overall width of the flexible film can be reduced, the structure of the driver of the display apparatus can be simplified.

The foregoing is illustrative of the inventive concept and is not to be construed as limiting thereof. Although some example embodiments of the inventive concept have been described, those skilled in the art will readily appreciate that many modifications are possible in the example embodiments without materially departing from the novel teachings and advantages of the inventive concept. Accordingly, all such modifications are intended to be included within the scope of the inventive concept as set forth in the claims. In the claims, means-plus-function clauses are intended to cover the structures described herein as performing the recited function and not only structural equivalents but also equivalent structures. Therefore, it is to be understood that the foregoing is illustrative of the inventive concept and is not to be construed as limited to the specific example embodiments disclosed, and that modifications to the disclosed example embodiments, as well as other example embodiments, are intended to be included within the scope of the appended claims. The inventive concept is defined by the following claims, with equivalents of the claims to be included therein.

What is claimed is:

1. A flexible film, comprising:
a flexible first layer;
a common ground wiring on the first layer;
an insulation layer on the first layer on which the common ground wiring is arranged;
a first ground wiring on the insulation layer, and connected to the common ground wiring through a first contact hole formed through the insulation layer;
a first signal line on the insulation layer and to which a first signal is applied;
a second signal line on the insulation layer, adjacent to the first signal line, and to which a second signal, which is an inverted signal of the first signal, is applied; and
a first sub-ground wiring on the insulation layer, and connected to the common ground wiring through a second contact hole formed through the insulation layer.

2. The flexible film of claim 1, further comprising a second ground wiring on the insulation layer, spaced apart from the first ground wiring, and electrically connected to the common ground wiring through a third contact hole formed through the insulation layer, and
wherein the first signal line, the second signal line, and the first sub-ground wiring are between the first ground wiring and the second ground wiring.

3. The flexible film of claim 2, further comprising:
a third signal line on the insulation layer between the first ground wiring and the second ground wiring; and
a fourth signal line on the insulation layer between the first ground wiring and the second ground wiring, and
wherein the third signal line and the fourth signal line are directly adjacent to each other,
a signal applied to the third signal wiring is an inverted signal of a signal applied to the fourth signal wiring, and
the first sub-ground wiring is between the second signal line and the third signal line.

4. The flexible film of claim 1, wherein the first layer has a U-shape, and
the first ground wiring, the first signal line, the second signal line, and the first sub-ground wiring extend along the U-shape.

5. The flexible film of claim 4, further comprising:
a first terminal at an end of the first signal line;
a second terminal at an end of the second signal line; and
a first ground terminal at an end of the first ground wiring, and
wherein a width of the first terminal is greater than a width of the first signal line, a width of the second terminal is greater than a width of the second signal line, and a width of the first ground terminal is greater than a width of the first ground wiring.

6. The flexible film of claim 5, wherein an interval between the first signal line and the second signal line is smaller than an interval between the first terminal and the second terminal.

7. The flexible film of claim 5, further comprising a second layer on the first ground wiring, the first signal line, and the first sub-ground wiring, and
wherein a terminal opening is formed through the second layer to expose the first terminal, the second terminal, and the first ground terminal, and the first sub-ground wiring does not overlap the terminal opening.

8. The flexible film of claim 1, wherein the common ground wiring has a mesh structure.

9. A display apparatus, comprising:
a display panel;
a first printed circuit board electrically connected to the display panel;
a second printed circuit board adjacent to the first printed circuit board and electrically connected to the display panel; and
a first U-film connecting the first printed circuit board and the second printed circuit board, and having a U-shape, and
wherein the first U-film comprises;
a flexible first layer;
a common ground wiring on the first layer;
an insulation layer on the first layer on which the common ground wiring is arranged;
a first ground wiring on the insulation layer, and connected to the common ground wiring through a first contact hole formed through the insulation layer;
a first signal line on the insulation layer and to which a first signal is applied;
a second signal line on the insulation layer, adjacent to the first signal line, and to which a second signal, which is an inverted signal of the first signal, is applied; and
a first sub-ground wiring on the insulation layer, and connected to the common ground wiring through a second contact hole formed through the insulation layer.

10. The display apparatus of claim 9, wherein the first U-film further comprises a second ground wiring on the insulation layer, spaced apart from the first ground wiring, and electrically connected to the common ground wiring through a third contact hole formed through the insulation layer, and
wherein the first signal line, the second signal line, and the first sub-ground wiring are between the first ground wiring and the second ground wiring.

11. The display apparatus of claim 10, wherein the first U-film further comprises:
a third signal line on the insulation layer between the first ground wiring and the second ground wiring; and
a fourth signal line on the insulation layer between the first ground wiring and the second ground wiring, and
wherein the third signal line and the fourth signal line are directly adjacent to each other,
a signal applied to the fourth signal wiring is an inverted signal of a signal applied to the third signal wiring, and
the first sub-ground wiring is between the second signal line and the third signal line.

12. The display apparatus of claim 11, wherein the first U-film further comprises:
a first terminal;
a second terminal; and
a first ground terminal at an end of the first ground wiring, and
wherein a width of the first terminal is greater than a width of the first signal line, a width of the second terminal is greater than a width of the second signal line, and a width of the first ground terminal is greater than a width of the first ground wiring.

13. The display apparatus of claim 12, wherein an interval between the first signal line and the second signal line of the first U-film is smaller than an interval between the first terminal and the second terminal.

14. The display apparatus of claim 13, wherein the first U-film further comprises a second layer on the first ground wiring, the first signal line, and the first sub-ground wiring, and
a terminal opening is formed through the second layer to expose the first terminal, the second terminal, and the first ground terminal, and the first sub-ground wiring does not overlap the terminal opening

15. The display apparatus of claim 14, wherein the first printed circuit board comprises a first connector,
the second printed circuit board comprises a second connector, and
the first terminal, the second terminal, and the first ground terminal of the first U-film are connected to the first connector or the second connector through the terminal opening.

16. The display apparatus of claim 15, wherein the first U-film further comprises a handle on a surface of the first layer opposite to a surface on which the common ground wiring is arranged.

17. The display apparatus of claim 9, wherein the common ground wiring has a mesh structure.

18. The display apparatus of claim 9, further comprising:
a host line electrically connected to the second printed circuit board; and
a driving substrate electrically connected to the host line to generate a signal to drive the display panel.

19. The display apparatus of claim 9, wherein the first printed circuit board comprises a first data driving chip, and the second printed circuit board comprises a second data driving chip.

20. A display apparatus, comprising:
a display panel;
a printed circuit board electrically connected to the display panel, and comprising a connector; and
a flexible film connected to the printed circuit board through the connector, and
wherein the flexible film comprises:
a first layer;
a common ground wiring on the first layer and extending in a first direction;
an insulation layer on the common ground wiring;
a first sub-ground wiring on the insulation layer, connected to the common ground wiring through a first contact hole formed through the insulation layer, and extending in a second direction crossing the first direction;
a second sub-ground wiring on the insulation layer, connected to the common ground wiring through a second contact hole formed through the insulation layer, and extending in the second direction; and
first and second signal lines on the insulation layer, paired adjacent to each other, and between the first sub-ground wiring and the second sub-ground wiring.
